(19) United States
(12) Patent Application Publication
(10) Pub. No.: US 2024/0395681 A1
(43) Pub. Date: Nov. 28, 2024

(54) SEMICONDUCTOR DEVICE

(71) Applicant: ROHM CO., LTD., Kyoto-shi (JP)

(72) Inventors: Bungo TANAKA, Kyoto-shi (JP); Toshiyuki KANAYA, Kyoto-shi (JP)

(21) Appl. No.: 18/789,087

(22) Filed: Jul. 30, 2024

Related U.S. Application Data
(63) Continuation of application No. PCT/JP2023/001892, filed on Jan. 23, 2023.

(30) Foreign Application Priority Data
Feb. 8, 2022 (JP) 2022-017651

(51) Int. Cl. H01L 23/498; H01L 23/00; H01L 23/31; H01L 23/522; H01L 25/18

(52) U.S. Cl. CPC H01L 23/49811; H01L 23/3121; H01L 23/49838; H01L 23/5228; H01L 24/29; H01L 24/32; H01L 24/45; H01L 24/48; H01L 24/73; H01L 25/18; H01L 2224/29139; H01L 2224/32225; H01L 2224/45144; H01L 2224/48137; H01L 2224/48155; H01L 2224/73265; H01L 2924/1424; H01L 2924/1815; H01L 2924/19043

(57) ABSTRACT

A semiconductor device includes a first semiconductor element, a first terminal electrically connected to the first semiconductor element, a second terminal electrically connected to the first semiconductor element and spaced apart from the first terminal in a first direction, and a sealing resin covering the first semiconductor element and a part of each of the first terminal and the second terminal. The sealing resin includes a first side surface facing in a second direction orthogonal to the first direction and located closest to the first terminal and the second terminal in the second direction. The first terminal and the second terminal are spaced apart from the first side surface.

### TECHNICAL FIELD

The present disclosure relates to a semiconductor device.

### BACKGROUND ART

In recent years, electric vehicles have become widespread. JP-A-2012-95427 discloses an example of a circuit for monitoring the voltage of a battery installed in an electric vehicle and controlling an inverter. The circuit allows prevention of excessive voltage supply to the inverter that drives the motor.

Among the circuits disclosed in JP-A-2012-95427, the resistor voltage detection circuit and the high-voltage-battery detection circuit are the circuits necessary for monitoring the voltage of the battery installed in an electric vehicle. These two circuits are composed of a plurality of ICs. The circuits disclosed in JP-A-2012-95427 can be made more compact if these two circuits are combined, by using as few ICs as possible, into a single semiconductor device with a plurality of terminals electrically connected to the ICs. However, of the plurality of terminals of the semiconductor device, some of them connected to the battery receive a high voltage. If an attempt is made to further miniaturize the semiconductor device, the distance between terminals reduces. In such a case, electric discharge may occur between the terminals to which a high voltage is applied.

### BRIEF DESCRIPTION OF THE DRAWINGS

FIG. 1 is a plan view of a semiconductor device according to a first embodiment of the present disclosure.

FIG. 2 is a plan view corresponding to FIG. 1 as seen through the sealing resin.

FIG. 3 is a bottom view of the semiconductor device shown in FIG. 1.

FIG. 4 is a left side view of the semiconductor device shown in FIG. 1.

FIG. 5 is a right side view of the semiconductor device shown in FIG. 1.

FIG. 6 is a sectional view taken along line VI-VI in FIG. 2.

FIG. 7 is a sectional view taken along line VII-VII in FIG. 2.

FIG. 8 is a sectional view taken along line VIII-VIII in FIG. 2.

FIG. 9 is a block diagram of a circuit formed in the semiconductor device shown in FIG. 1.

FIG. 10 is a plan view of a semiconductor device according to a second embodiment of the present disclosure as seen through the sealing resin.

FIG. 11 is a bottom view of the semiconductor device shown in FIG. 10.

FIG. 12 is a sectional view taken along line XII-XII in FIG. 10.

FIG. 13 is a sectional view taken along line XIII-XIII in FIG. 10.

FIG. 14 is a plan view of a semiconductor device according to a third embodiment of the present disclosure as seen through the sealing resin.

FIG. 15 is a bottom view of the semiconductor device shown in FIG. 14.

FIG. 16 is a sectional view taken along line XVI-XVI in FIG. 14.

FIG. 17 is a sectional view taken along line XVII-XVII in FIG. 14.

FIG. 18 is a plan view of a semiconductor device according to a fourth embodiment of the present disclosure.

FIG. 19 is a bottom view of the semiconductor device shown in FIG. 18.

FIG. 20 is a left side view of the semiconductor device shown in FIG. 18.

FIG. 21 is a sectional view taken along line XXI-XXI in FIG. 18.

FIG. 22 is a sectional view taken along line XXII-XXII in FIG. 18.

FIG. 23 is a plan view of a semiconductor device according to a fifth embodiment of the present disclosure.

FIG. 24 is a plan view corresponding to FIG. 23 as seen through the sealing resin.

FIG. 25 is a sectional view taken along line XXV-XXV in FIG. 24.

FIG. 26 is a sectional view taken along line XXVI-XXVI in FIG. 24.

FIG. 27 is a sectional view taken along line XXVII-XXVII in FIG. 24.

### DETAILED DESCRIPTION OF EMBODIMENTS

The following describes modes for carrying out the present disclosure with reference to the drawings.

### First Embodiment

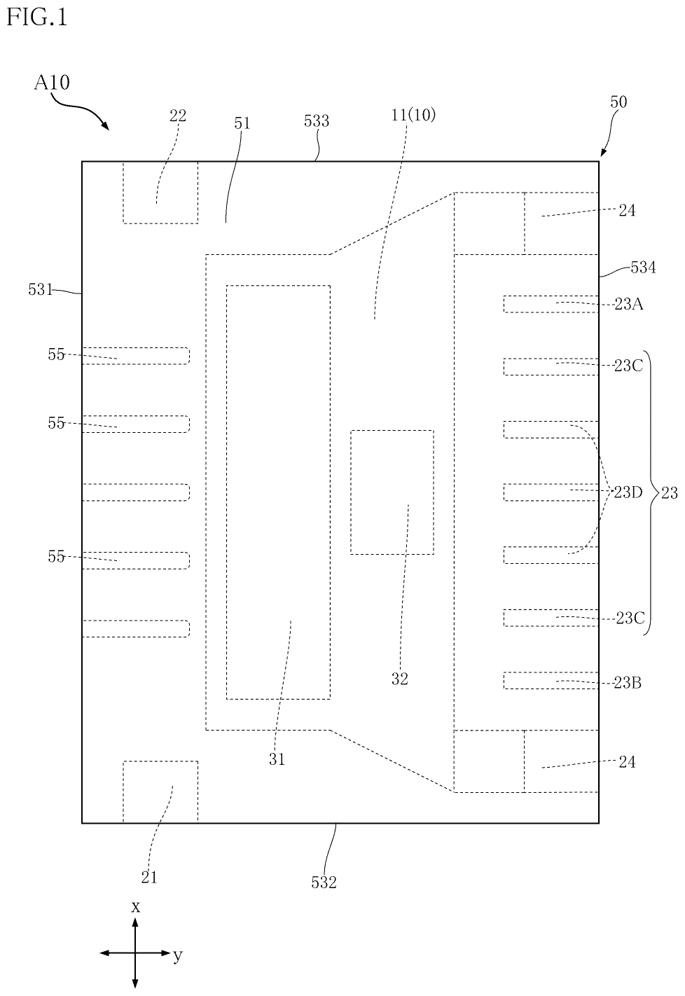

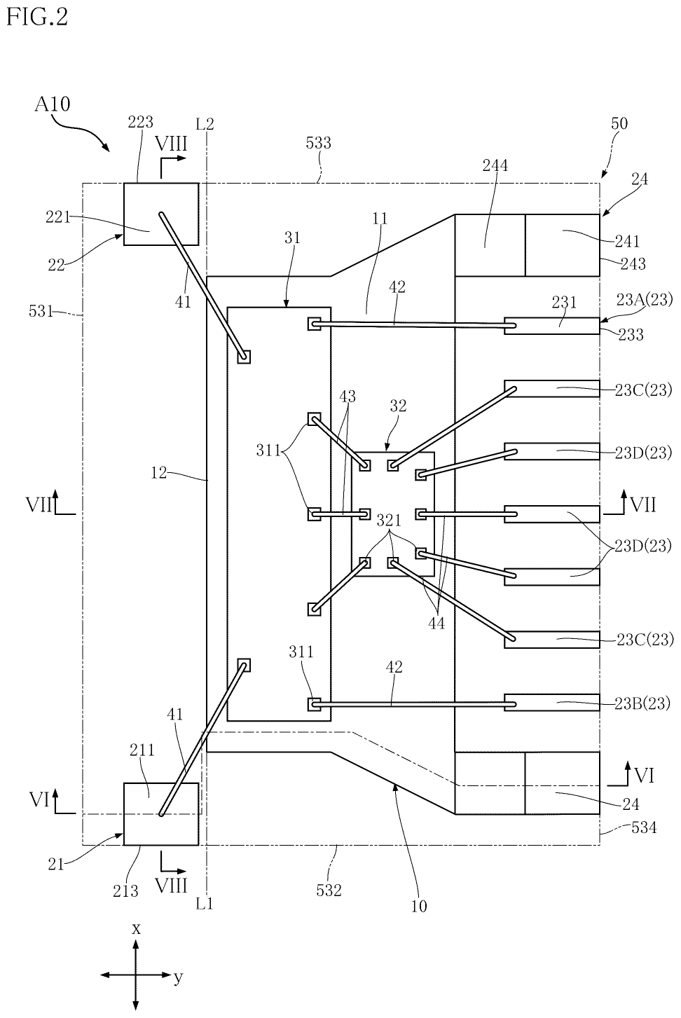

A semiconductor device A10 according to a first embodiment of the present disclosure will be described based on FIGS. 1 to 8. The semiconductor device A10 may be used, for example, for monitoring the voltage of a battery installed in an electric vehicle. The package type of the semiconductor device A10 is the QFN (Quad Flat Non-leaded package). The semiconductor device A10 includes a die pad 10, a first terminal 21, a second terminal 22, a plurality of third terminals 23, two fourth terminals 24, a first semiconductor element 31, a second semiconductor element 32, and a sealing resin 50. In FIG. 2, the sealing resin 50 is transparent for the convenience of understanding. The outline of the sealing resin 50 is shown by imaginary lines (two-dot chain lines) in FIG. 2. The VI-VI line is shown as a single-dot chain line in FIG. 2.

In the description of the semiconductor device A10, the direction in which the first terminal 21 and the second terminal 22 are spaced apart from each other is referred to as the “first direction x” for convenience. A direction orthogonal to the first direction x is referred to as the “second direction y”. The direction orthogonal to the first direction x and the second direction y is referred to as the “third direction z”. The third direction z corresponds to the direction that is normal to the top surface 51, described later, of the sealing resin 50.

As shown in FIGS. 6 to 8, the sealing resin 50 covers the die pad 10, the first semiconductor element 31, the second semiconductor element 32, a part of the first terminal 21, a part of the second terminal 22, a part of each of the third terminals 23, and a part of each of the two fourth terminals 24. The sealing resin 50 is electrically insulating. The sealing resin 50 contains, for example, black epoxy resin. As shown in FIGS. 1 to 3, the sealing resin 50 has a top surface 51, a bottom surface 52, a first side surface 531, a second side surface 532, a third side surface 533, and a fourth side surface 534.

As shown in FIGS. 6 to 8, the bottom surface 52 faces one side in the third direction z. The top surface 51 faces away from the bottom surface 52 in the third direction z.

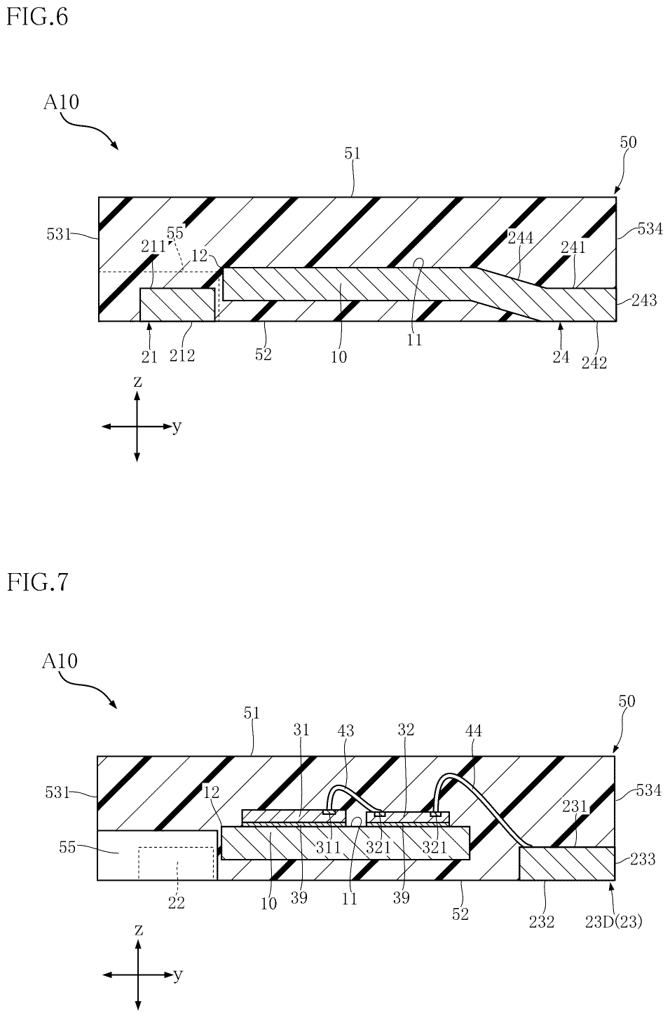

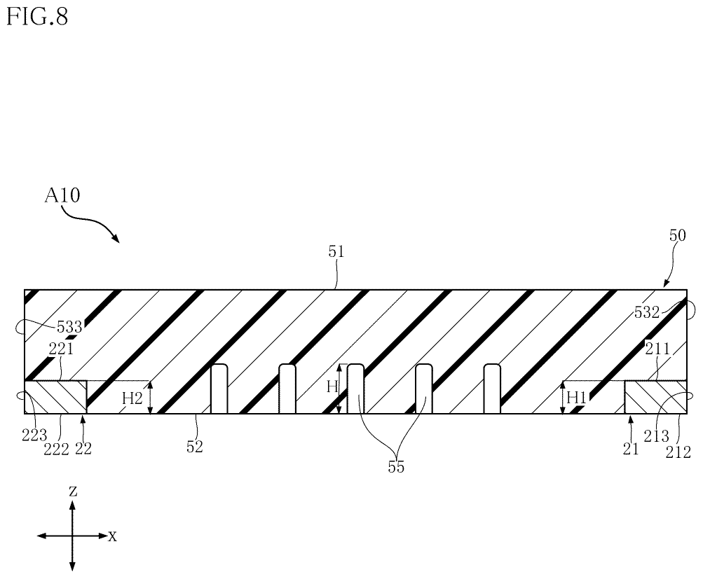

As shown in FIGS. 6 and 7, the first side surface 531 faces one side in the second direction y. The first side surface 531 is located closest to the first terminal 21 and the second terminal 22 in the second direction y. The second side surface 532 faces one side in the first direction x. The second side surface 532 is located closest to the first terminal 21 in the first direction x. The third side surface 533 faces away from the second side surface 532 in the first direction x. The fourth side surface 534 faces away from the first side surface 531 in the second direction y. The first side surface 531, the second side surface 532, the third side surface 533, and the fourth side surface 534 are connected to the bottom surface 52. The first side surface 531, the second side surface 532, the third side surface 533, and the fourth side surface 534 are also connected to the top surface 51.

As shown in FIG. 2, the die pad 10 is located between the first terminal 21 and the second terminal 22 in the first direction x. The die pad 10 contains a metal element. The metal element is, for example, copper (Cu). The die pad 10, the first terminal 21, the second terminal 22, the third terminals 23, and the two fourth terminals 24 are obtained from the same lead frame. As shown in FIGS. 1 and 2, the die pad 10 has a mount surface 11 and a first edge 12. The mount surface 11 faces the same side as the top surface 51 of the sealing resin 50 in the third direction z. As viewed in the third direction z, the first edge 12 extends in the first direction x and located closest to the first side surface 531 of the sealing resin 50.

As shown in FIG. 2, the dimension of the die pad 10 in the first direction x increases as it extends away from the side on which the first side surface 531 of the sealing resin 50 is located with respect to the first semiconductor element 31 in the second direction y. Also, the portion of the die pad 10 that is located opposite to the first edge 12 with respect to the first semiconductor element 31 in the second direction y protrudes toward the opposite sides in the first direction x with respect to the first edge 12. As shown in FIGS. 6 and 7, the die pad 10 is spaced apart from the bottom surface 52 of the sealing resin 50.

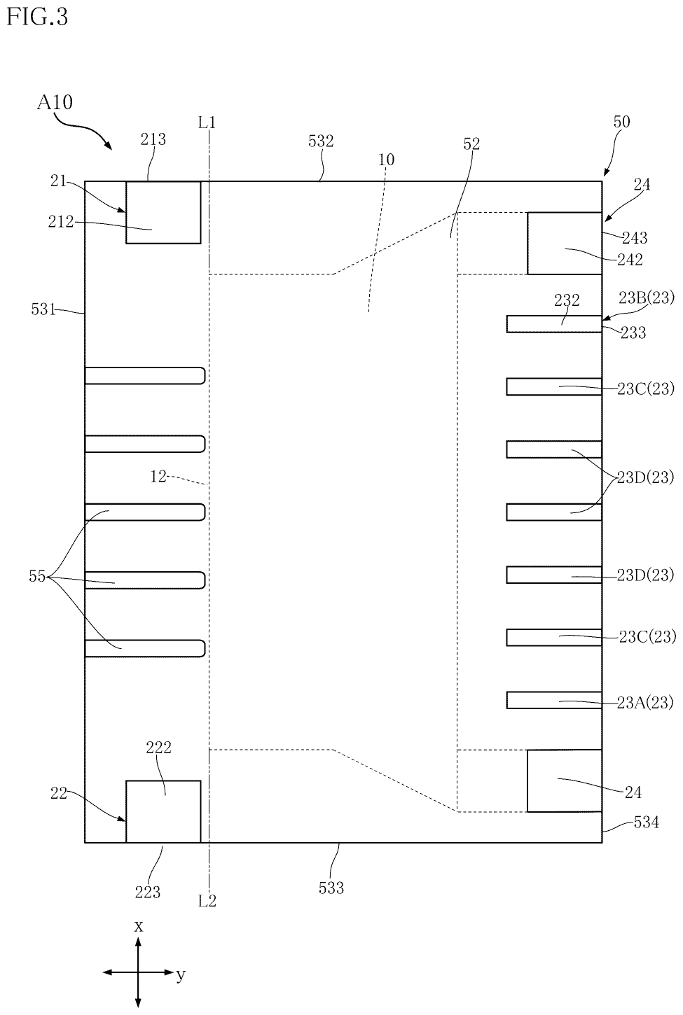

As shown in FIG. 1, the first terminal 21 is spaced apart from the first side surface 531 of the sealing resin 50. As shown in FIGS. 2 and 3, the first terminal 21 is located on one side in the first direction x of the first edge 12 of the die pad 10. In the semiconductor device A10, the first terminal 21 is located opposite to the fourth side surface 534 of the sealing resin 50 with respect to the first edge 12 in the second direction y. Also, the first terminal 21 is spaced apart from the first extension line L1 extending from a first end of the first edge 12 in the first direction x.

As shown in FIGS. 2, 3, and 8, the first terminal 21 has a first obverse surface 211, a first reverse surface 212, and a first end surface 213. The first obverse surface 211 faces the same side as the top surface 51 of the sealing resin 50 in the third direction z. In the semiconductor device A10, the first obverse surface 211 is covered with the sealing resin 50. The first reverse surface 212 faces away from the first obverse surface 211 in the third direction z. The first reverse surface 212 is exposed to the outside from the bottom surface 52 of the sealing resin 50. The first end surface 213 faces the same side as the second side surface 532 of the sealing resin 50 in the first direction x. The first end surface 213 is exposed to the outside from the second side surface 532.

As shown in FIG. 1, the second terminal 22 is spaced apart from the first side surface 531 of the sealing resin 50. The second terminal 22 is spaced apart from the first terminal 21 in the first direction x. As shown in FIGS. 2 and 3, the second terminal 22 is located opposite to the first terminal 21 with respect to the first edge 12 of the die pad 10 in the first direction x. Thus, the first terminal 21 and the second terminal 22 are located on opposite sides of the first edge 12 in the first direction x. The second terminal 22 is located opposite to the fourth side surface 534 of the sealing resin 50 with respect to the first edge 12 in the second direction y. Also, the second terminal 22 is spaced apart from the second extension line L2 extending from a second end of the first edge 12 in the first direction x.

As shown in FIGS. 2, 3, and 8, the second terminal 22 has a second obverse surface 221, a second reverse surface 222, and a second end surface 223. The second obverse surface 221 faces the same side as the top surface 51 of the sealing resin 50 in the third direction z. In the semiconductor device A10, the second obverse surface 221 is covered with the sealing resin 50. The second reverse surface 222 faces away from the second obverse surface 221 in the third direction z. The second reverse surface 222 is exposed to the outside from the bottom surface 52 of the sealing resin 50. The second end surface 223 faces the same side as the third side surface 533 of the sealing resin 50 in the second direction y. The second end surface 223 is exposed to the outside from the third side surface 533.

As shown in FIG. 2, the plurality of third terminals 23 are located opposite to the first side surface 531 of the sealing resin 50 with respect to the die pad 10 in the second direction y. The third terminals 23 are arranged along the first direction x. The distance between two adjacent third terminals 23 in the first direction x is shorter than the distance between the first terminal 21 and the second terminal 22. The third terminals 23 include an A-terminal 23A, a B-terminal 23B, two C-terminals 23C, and a plurality of D-terminals 23D.

As shown in FIGS. 2, 3, and 7, each of the third terminals 23 has a third obverse surface 231, a third reverse surface 232, and a third end surface 223. The third obverse surface 231 faces the same side as the top surface 51 of the sealing resin 50 in the third direction z. In the semiconductor device A10, the third obverse surface 231 is covered with the sealing resin 50. The third reverse surface 232 faces away from the third obverse surface 231 in the third direction z. The third reverse surface 232 is exposed to the outside from the bottom surface 52 of the sealing resin 50. The third end surface 233 faces the same side as the fourth side surface 534 of the sealing resin 50 in the second direction y. As shown in FIG. 5, the third end surface 233 is exposed to the outside from the fourth side surface 534.

As shown in FIG. 2, the two fourth terminals 24 are spaced apart from each other in the first direction x and supports the die pad 10. The third terminals 23 are located between the two fourth terminals 24 in the first direction x.

As shown in FIGS. 2, 3, and 6, each of the two fourth terminals 24 has a fourth obverse surface 241, a fourth reverse surface 242, a fourth end surface 243, and a connecting surface 244. The fourth obverse surface 241 faces the same side as the top surface 51 of the sealing resin 50 in the third direction z. In the semiconductor device A10, the fourth obverse surface 241 is covered with the sealing resin 50. The fourth reverse surface 242 faces away from the fourth obverse surface 241 in the third direction z. The fourth reverse surface 242 is exposed to the outside from the bottom surface 52 of the sealing resin 50. The fourth end surface 243 faces the same side as the fourth side surface 534 of the sealing resin 50 in the second direction y. As shown in FIG. 5, the fourth end surface 243 is exposed to the outside from the fourth side surface 534. The connecting surface 244 is connected to the fourth obverse surface 241 and the mount surface 11 of the die pad 10. The connecting surface 244 is inclined with respect to the fourth obverse surface 241 and the mount surface 11. The connecting surface 244 is covered with the sealing resin 50.

As shown in FIGS. 2 and 7, the first semiconductor element 31 and the second semiconductor element 32 are mounted on the mount surface 11 of the die pad 10. The first semiconductor element 31 and the second semiconductor element 32 are both integrated (ICs). circuits The second semiconductor element 32 is located between the first semiconductor element 31 and the third terminals 23 in the second direction y. As shown in FIG. 7, the first semiconductor element 31 and the second semiconductor element 32 are bonded to the mount surface 11 via bonding layers 39. The bonding layers 39 are made of, for example, a paste (so-called Ag paste) mainly composed of epoxy resin mixed with silver.

As shown in FIG. 2, the first semiconductor element 31 has a plurality of first electrodes 311. The first electrodes 311 are electrically connected to a circuit formed in the first semiconductor element 31. As shown in FIG. 2, the second semiconductor element 32 has a plurality of second electrodes 321. The second electrodes 321 are electrically connected to a circuit formed in the second semiconductor element 32.

As shown in FIG. 2, the semiconductor device A10 further includes two first wires 41, a plurality of second wires 42, a plurality of third wires 43, and a plurality of fourth wires 44. The composition of these wires includes, for example, gold (Au). These wires are covered with the sealing resin 50.

As shown in FIG. 2, one of the two first wires 41 is connected to a first electrode 311 of the first semiconductor element 31 and the first obverse surface 211 of the first terminal 21, and the other one to another first electrode 311 of the first semiconductor element 31 and the second obverse surface 221 of the second terminal 22. Thus, the first terminal 21 and the second terminal 22 are electrically connected to the first semiconductor element 31.

As shown in FIG. 2, one of the second wires 42 is connected to a first electrode 311 of the first semiconductor element 31 and the third obverse surface 231 of the A-terminal 23A, and the other one to another first electrode 311 of the first semiconductor element 31 and the third obverse surface 231 of the B-terminal 23B. Thus, the first semiconductor element 31 is electrically connected to the A-terminal 23A and the B-terminal 23B.

As shown in FIG. 2, the third wires 43 are individually connected to first electrodes 311 of the first semiconductor element 31 and second electrodes 321 of the second semiconductor element 32. Thus, the second semiconductor element 32 is connected electrically to the first semiconductor element 31.

As shown in FIG. 2, the fourth wires 44 are individually connected to second electrodes 321 of the second semiconductor element 32 and the third obverse surfaces 231 of the two C-terminals 23C or the third obverse surfaces 231 of the D-terminals 23D. Thus, the second semiconductor element 32 is electrically connected to the two C-terminals 23C and the plurality of D-terminals 23D.

As shown in FIGS. 1, 3, and 4, the sealing resin 50 has a plurality of recesses 55. The recesses 55 are located between the first terminal 21 and the second terminal 22 in the first direction x. As shown in FIGS. 6 and 7, the recesses 55 overlap with the first terminal 21 and the second terminal 22 as viewed in the first direction x. The recesses 55 are recessed from the bottom surface 52 and connected to the first side surface 531. The recesses 55 extend in the second direction y. In the semiconductor device A10, the recesses 55 are spaced apart from the die pad 10 as viewed in the third direction z.

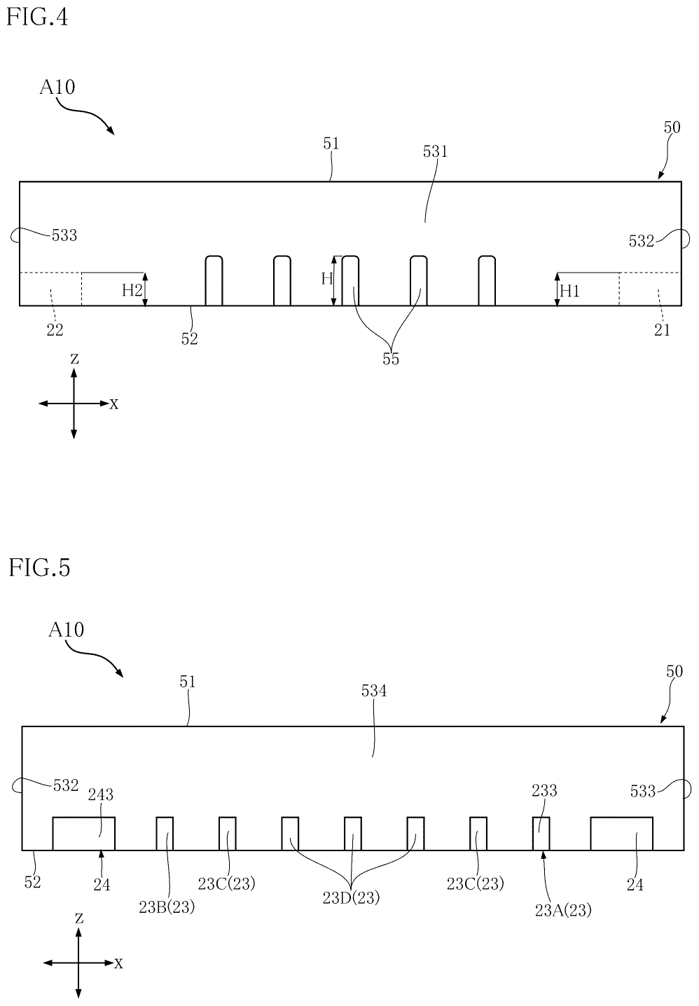

As shown in FIGS. 4 and 8, the dimension H of each recess 55 in the third direction z is greater than the respective dimensions H1 and H2 of the first terminal 21 and the second terminal 22 in the third direction z.

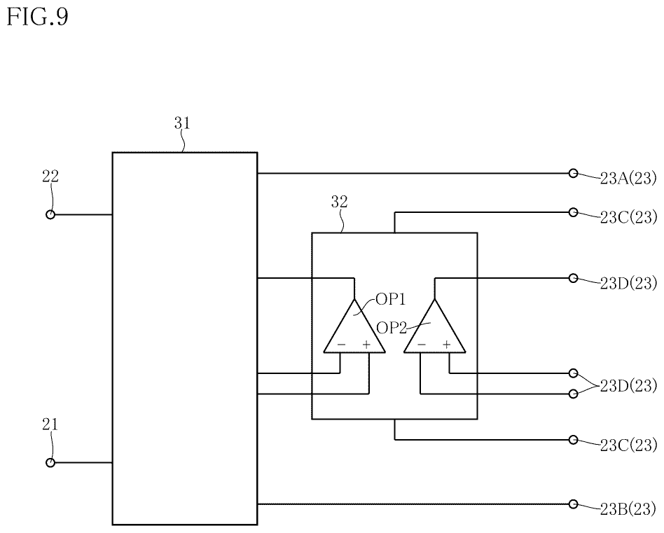

Next, the circuit configuration of the semiconductor device A10 will be described based on FIG. 9.

The first semiconductor element 31 includes a step-down circuit formed therein. The step-down circuit includes a plurality of resistor elements. The first terminal 21 and the second terminal 22 are connected to a battery (not shown) to be monitored. The first terminal 21 is a positive electrode. The second terminal 22 is a negative electrode. The battery voltage applied to the first terminal 21 and the second terminal 22 is converted to a weak electrical signal by the step-down circuit of the first semiconductor element 31.

As shown in FIG. 9, the second semiconductor element 32 includes two operational amplifiers OP1 and OP2. However, the second semiconductor element 32 may not include the operational amplifier OP2. The operational amplifier OP1 amplifies the weak electrical signal converted by the first semiconductor element 31 and outputs it to the A-terminal 23A via the first semiconductor element 31. This allows the battery voltage to be monitored.

The B-terminal 23B is the ground of the first semiconductor element 31. The power supply for driving the second semiconductor element 32 is connected to two C terminals 23C. The D-terminals 23D are electrically connected to the operational amplifier OP2. An electrical signal created by another control circuit (not shown) based on the electrical signal outputted from the A-terminal 23A is inputted to the operational amplifier OP2. Thus, the operational amplifier OP2 removes high-frequency noise contained in the electrical signal outputted from the A-terminal 23A, which allows more accurate monitoring.

Next, the effects of the semiconductor device A10 will be described.

The semiconductor device A10 includes the sealing resin 50 covering a part of each of the first terminal 21 and the second terminal 22, and the first semiconductor element 31 electrically connected to the first terminal 21 and the second terminal 22 and covered with the sealing resin 50. The second terminal 22 is spaced apart from the first terminal 21 in the first direction x. The sealing resin 50 has the first side surface 531 facing in the second direction y and located closest to the first terminal 21 and the second terminal 22 in the second direction y. The first terminal 21 and the second terminal 22 are spaced apart from the first side surface 531. Such a configuration increases the creepage distance of the sealing resin 50 (the distance along the surface of the sealing resin 50) from the first terminal 21 to the second terminal 22 through the first side surface 531. Thus, it is possible to reduce the distance in the first direction x between the first terminal 21 and the second terminal 22 while suppressing the occurrence of electric discharge from the first terminal 21 to the second terminal 22 when a high voltage relative to the second terminal 22 is applied to the first terminal 21. Thus, the semiconductor device A10 having the above configuration allows miniaturization of the device while suppressing electric discharge between the terminals.

The semiconductor device A10 further includes the die pad 10 on which the first semiconductor element 31 is mounted. As viewed in the third direction z, the die pad 10 has the first edge 12 extending in the first direction x. The first edge 12 is located closest to the first side surface 531 of the sealing resin 50. The first terminal 21 and the second terminal 22 are located on opposite sides of the first edge 12 in the first direction x. Such a configuration provides a sufficient distance between the third terminals 23 and the first and second terminals 21 and 22, whereby electric discharge between the first terminal 21 and the third terminals 23 is suppressed.

The sealing resin 50 has recesses 55 located between the first terminal 21 and the second terminal 22 in the first direction x. The recesses 55 are recessed from the bottom surface 52 of the sealing resin 50. The recesses 55 overlap with the first terminal 21 and the second terminal 22 as viewed in the first direction x. Such a configuration increases the creepage distance of the sealing resin 50 from the first terminal 21 to the second terminal 22 through the bottom surface 52, whereby electric discharge between the first terminal and the second terminal 22 can be effectively suppressed.

The recesses 55 extend in the second direction y. Also, the dimension H of each recess 55 in the third direction z is greater than the respective dimensions H1 and H2 of the first terminal 21 and the second terminal 22 in the third direction z (see FIG. 8). Thus, as viewed in the first direction x, the entirety of each of the first terminal 21 and the second terminal 22 overlaps with the recesses 55 (see FIGS. 6 and 7). This allows electric discharge between the first terminal 21 and the second terminal 22 to be suppressed more effectively.

The semiconductor device A10 further includes two fourth terminals 24 spaced apart from each other in the first direction x and supporting the die pad 10. The two fourth terminals 24 are spaced apart from the second side surface 532 and the third side surface 533 of the sealing resin 50. The third terminals 23 are located between the two fourth terminals 24 in the first direction x. With such a configuration, only the first terminal 21 and the second terminal 22 are exposed to the outside from the first side surface 531 and the second side surface 532. Thus, electric discharge between the first terminal 21 and the third terminals 23 is suppressed more effectively.

The dimension of the die pad 10 in the first direction x increases as it extends away from the side on which the first side surface 531 of the sealing resin 50 is located with respect to the first semiconductor element 31 in the second direction y. Also, the portion of the die pad 10 that is located opposite to the first edge 12 with respect to the first semiconductor element 31 in the second direction y protrudes toward the opposite sides in the first direction x with respect to the first edge 12. Such a configuration increases the distance between the two fourth terminals 24 and hence increases the distance between adjacent two third terminals 23. This reduces mutual interference of noise at the plurality of third terminals 23.

The first terminal 21 is exposed to the outside from the second side surface 532 of the sealing resin 50. The second terminal 22 is exposed to the outside from the third side surface 533 of the sealing resin 50. With such a configuration, when the semiconductor device A10 is mounted on a circuit board, solder fillets are easily formed on the portion of the first terminal 21 (the first end surface 213) that is exposed to the outside from the second side surface 532 and the portion of the second terminal 22 (the second end surface 223) that is exposed to the outside from the third side surface 533. Thus, the bonding strength of the semiconductor device A10 to the circuit board can be improved.

### Second Embodiment

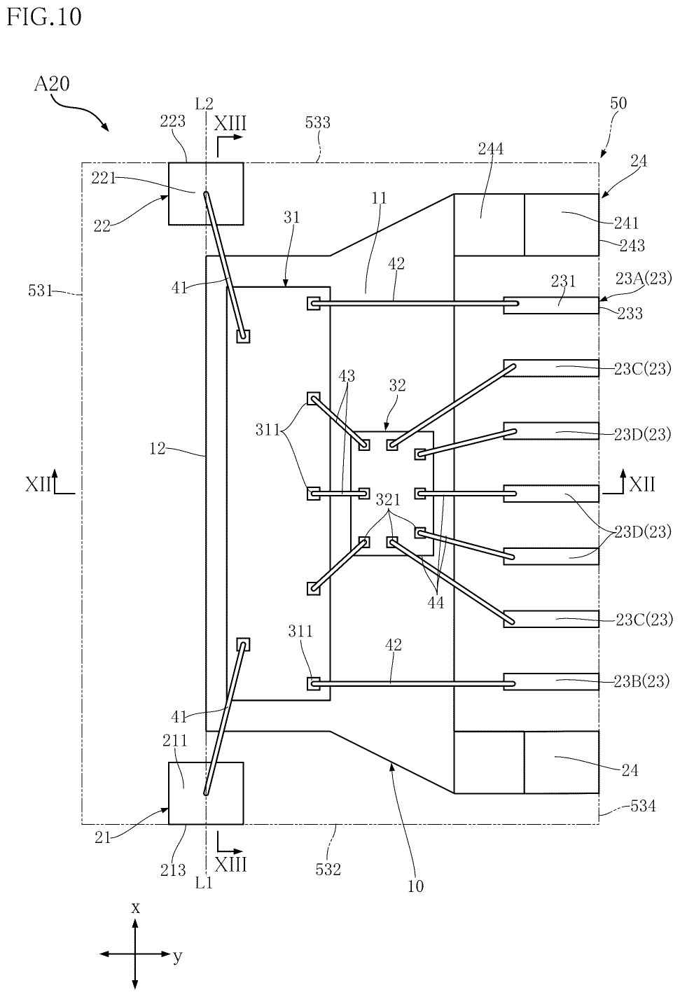

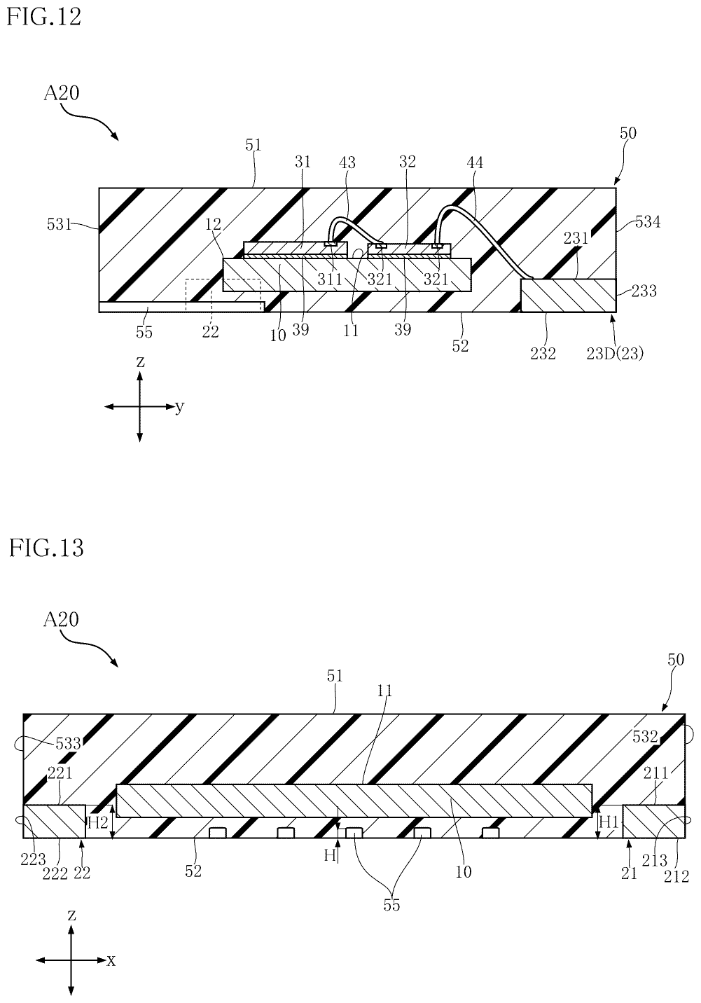

A semiconductor device A20 according to a second embodiment of the present disclosure will be described based on FIGS. 10 to 13. In these figures, the elements that are identical or similar to those of the semiconductor device A10 described above are denoted by the same reference signs, and the descriptions thereof are omitted. In FIG. 10, the sealing resin 50 is transparent for the convenience of understanding. In FIG. 10, the outline of the sealing resin 50 is shown by imaginary lines.

The semiconductor device A20 differs from the semiconductor device A10 in the configurations of the first terminal 21 and the second terminal 22 and the configuration of the recesses 55 in the sealing resin 50.

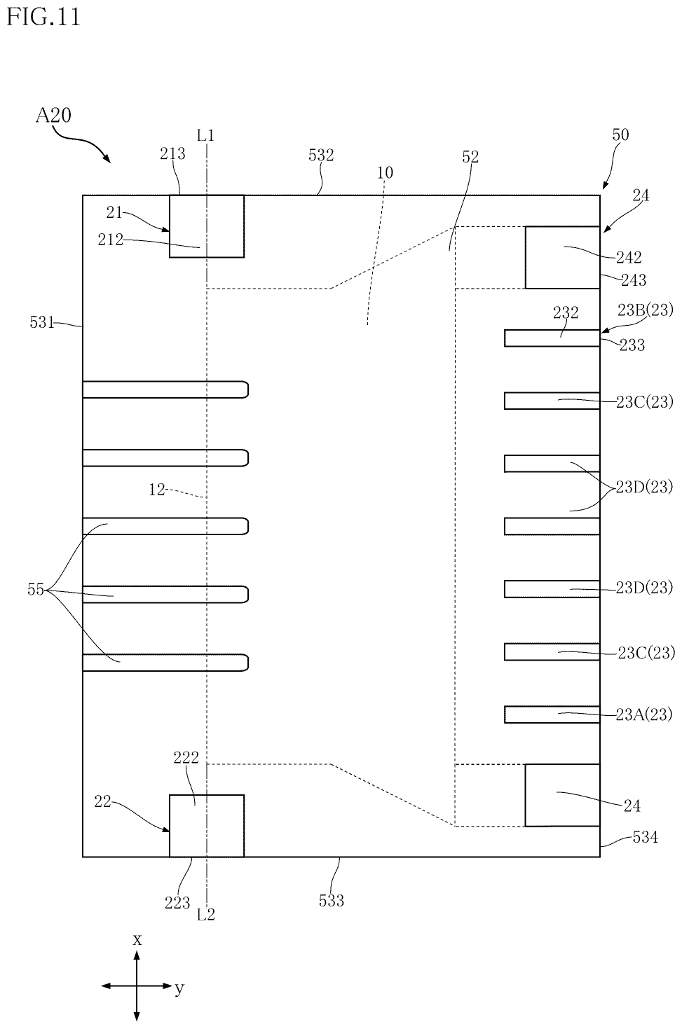

As shown in FIGS. 10 and 11, as viewed in the third direction z, the first terminal 21 overlaps with the first extension line L1 extending from the first end of the first edge 12 of the die pad 10 in the first direction x. As viewed in the third direction z, the second terminal 22 overlaps with the second extension line L2 extending from the second end of the first edge 12 of the die pad 10.

As shown in FIGS. 11 to 13, the recesses 55 overlap with the die pad 10 as viewed in the third direction z. Therefore, the recesses 55 overlap with the first terminal 21 and the second terminal 22 as viewed in the first direction x.

As shown in FIG. 13, the dimension H of each recess 55 in the third direction z is smaller than the respective dimensions H1 and H2 of the first terminal 21 and the second terminal 22 in the third direction z.

Next, the effects of the semiconductor device A20 will be described.

The semiconductor device A20 includes the sealing resin 50 covering a part of each of the first terminal 21 and the second terminal 22, and the first semiconductor element 31 electrically connected to the first terminal 21 and the second terminal 22 and covered with the sealing resin 50. The second terminal 22 is spaced apart from the first terminal 21 in the first direction x. The sealing resin 50 has the first side surface 531 facing in the second direction y and located closest to the first terminal 21 and the second terminal 22 in the second direction y. The first terminal 21 and the second terminal 22 are spaced apart from the first side surface 531. The semiconductor device A20 having such a configuration also allows miniaturization of the device while suppressing electric discharge between the terminals. Further, the semiconductor device A20 has a configuration in common with the semiconductor device A10, thereby achieving the same effect as the semiconductor device A10.

In the semiconductor device A20, as viewed in the third direction z, the first terminal 21 overlaps with the first extension line L1 extending from the first end of the first edge 12 of the die pad 10 in the first direction x. As viewed in the third direction z, the second terminal 22 overlaps with the second extension line L2 extending from the second end of the first edge 12 of the die pad 10. Such a configuration makes longer the creepage distance of the sealing resin 50 from the first terminal 21 to the second terminal 22 through the first side surface 531 than in the configuration of the semiconductor device A10. Therefore, the electric discharge between the terminals is more effectively suppressed than in the case of the semiconductor device A10.

In the semiconductor device A20, the recesses 55 overlap with the die pad 10 as viewed in the third direction z. With this configuration, the recesses 55 overlap with the first terminal 21 and the second terminal 22 as viewed in the first direction x. Therefore, the creepage distance of the sealing resin 50 from the first terminal 21 to the second terminal 22 through the bottom surface 52 is substantially equal to that in the semiconductor device A10. Thus, the semiconductor device A20 also effectively suppresses electric discharge between the first terminal 21 and the second terminal 22.

### Third Embodiment

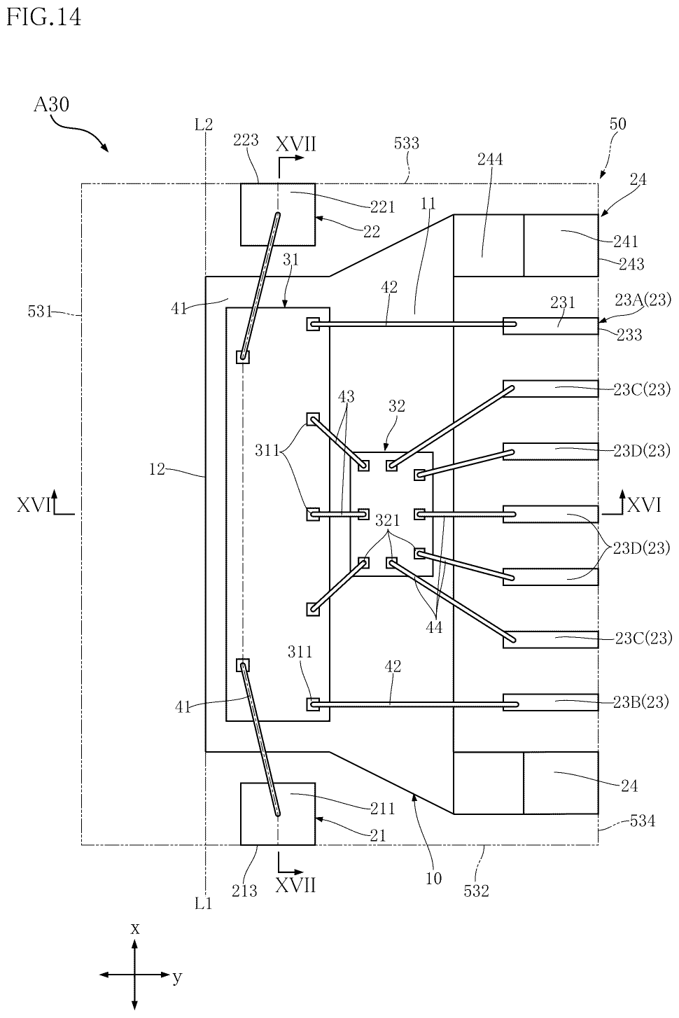

A semiconductor device A30 according to a third embodiment of the present disclosure will be described based on FIGS. 14 to 17. In these figures, the elements that are identical or similar to those of the semiconductor device A10 described above are denoted by the same reference signs, and the descriptions thereof are omitted. In FIG. 14, the sealing resin 50 is transparent for the convenience of understanding. In FIG. 14, the outline of the sealing resin 50 is shown by imaginary lines. The XVII-XVII line is shown as a single-dot chain line in FIG. 14.

The semiconductor device A30 differs from the semiconductor device A10 in the configurations of the first terminal 21 and the second terminal 22 and the configuration of the recesses 55 in the sealing resin 50.

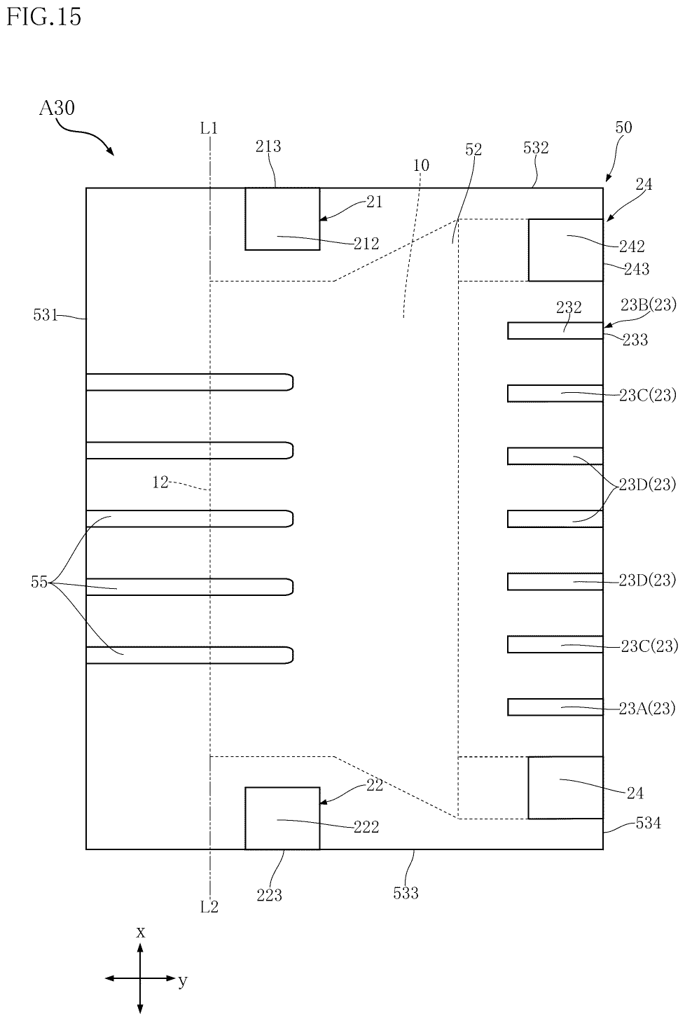

As shown in FIGS. 14 and 15, as viewed in the third direction z, the first terminal 21 and the second terminal 22 are located opposite to the first side surface 531 of the sealing resin 50 with respect to the first edge 12 of the die pad 10 in the second direction y. That is, the first terminal 21 is spaced apart from the first extension line L1 extending from the first end of the first edge 12 of the die pad 10 in the first direction x. As viewed in the third direction z, the second terminal 22 is spaced apart from the second extension line L2 extending from the second end of the first edge 12 of the die pad 10.

As shown in FIGS. 15 to 17, the recesses 55 overlap with the die pad 10 as viewed in the third direction z. Therefore, the recesses 55 overlap with the first terminal 21 and the second terminal 22 as viewed in the first direction x.

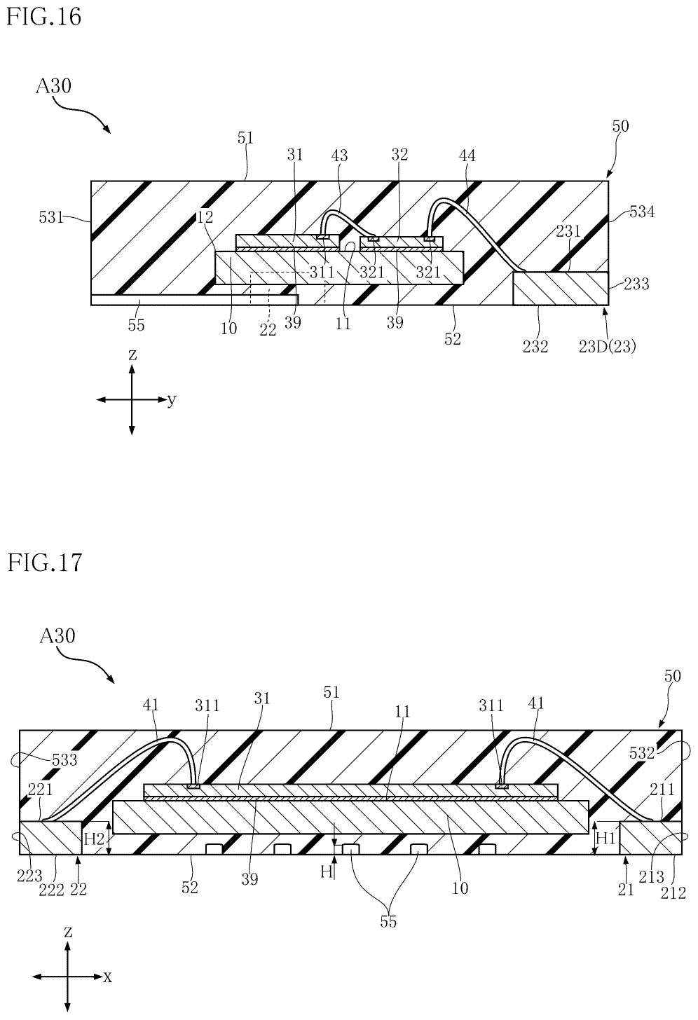

As shown in FIG. 17, the dimension H of each recess 55 in the third direction z is smaller than the respective dimensions H1 and H2 of the first terminal 21 and the second terminal 22 in the third direction z.

Next, the effects of the semiconductor device A30 will be described.

The semiconductor device A30 includes the sealing resin 50 covering a part of each of the first terminal 21 and the second terminal 22, and the first semiconductor element 31 electrically connected to the first terminal 21 and the second terminal 22 and covered with the sealing resin 50. The second terminal 22 is spaced apart from the first terminal 21 in the first direction x. The sealing resin 50 has the first side surface 531 facing in the second direction y and located closest to the first terminal 21 and the second terminal 22 in the second direction y. The first terminal 21 and the second terminal 22 are spaced apart from the first side surface 531. The semiconductor device A30 having such a configuration also allows miniaturization of the device while suppressing electric discharge between the terminals. Further, the semiconductor device A30 has a configuration in common with the semiconductor device A10, thereby achieving the same effect as the semiconductor device A10.

In the semiconductor device A30, as viewed in the third direction z, the first terminal 21 and the second terminal 22 are located opposite to the first side surface 531 of the sealing resin 50 with respect to the first edge 12 of the die pad 10 in the second direction y. Such a configuration makes longer the creepage distance of the sealing resin 50 from the first terminal 21 to the second terminal 22 through the first side surface 531 than in the configuration of the semiconductor device A20. Therefore, the electric discharge between the terminals is more effectively suppressed than in the case of the semiconductor device A10.

### Fourth Embodiment

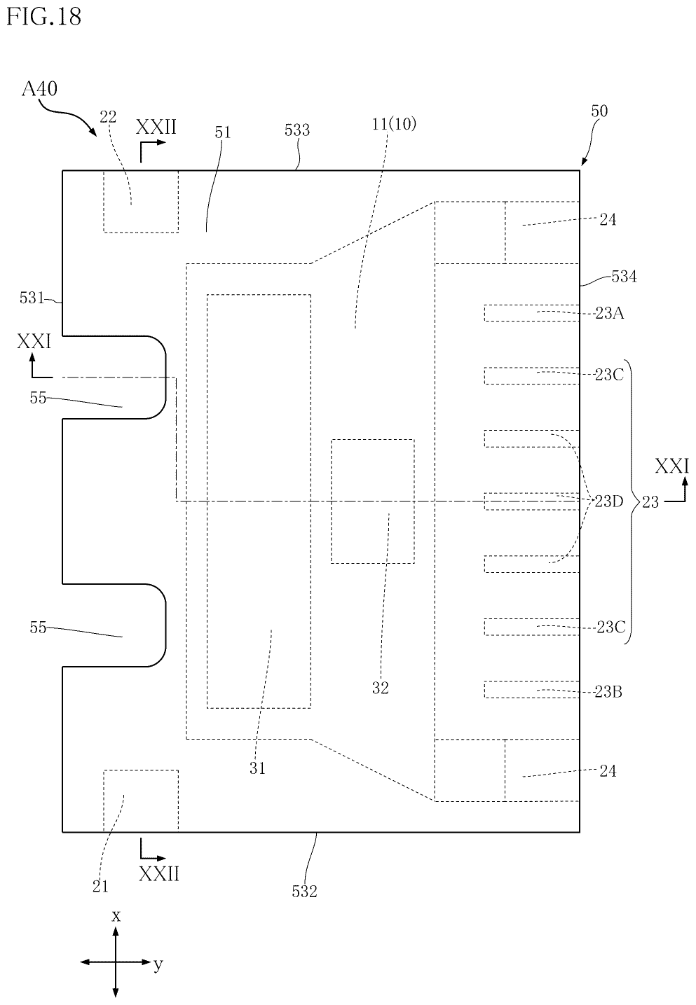

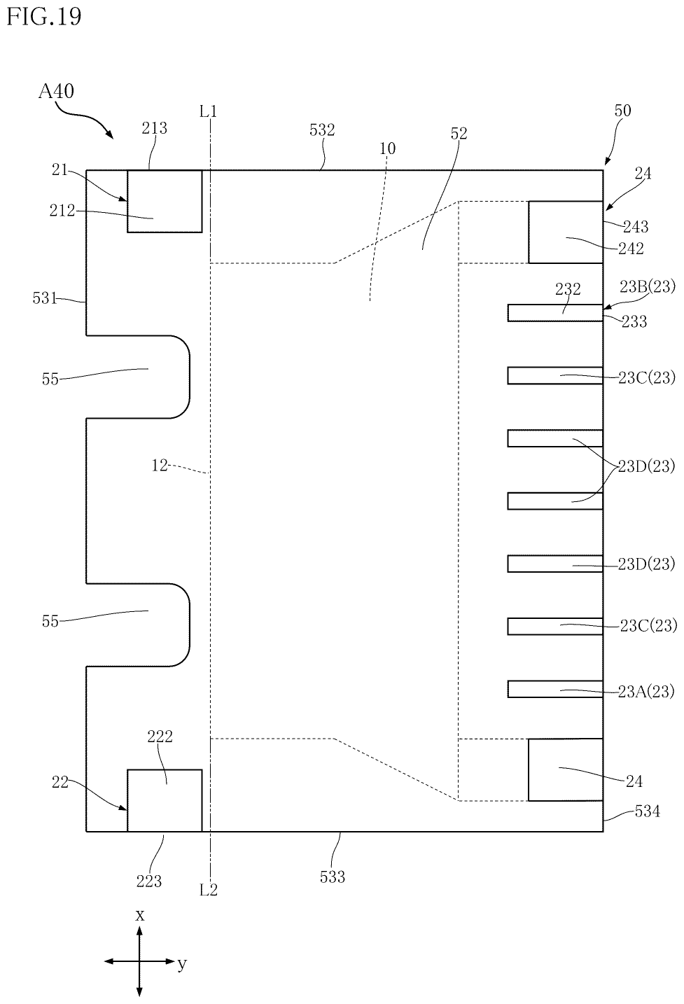

A semiconductor device A40 according to a fourth embodiment of the present disclosure will be described based on FIGS. 18 to 22. In these figures, the elements that are identical or similar to those of the semiconductor device A10 described above are denoted by the same reference signs, and the descriptions thereof are omitted. The XXI-XXI line is shown as a single-dot chain line in FIG. 18.

The semiconductor device A40 differs from the semiconductor device A10 in the configuration of the recesses 55 in the sealing resin 50.

As shown in FIGS. 18 to 21, the recesses 55 are recessed from the first side surface 531 of the sealing resin 50. The recesses 55 are connected to the top surface 51 of sealing resin 50 and the bottom surface 52 of the sealing resin 50. As viewed in the first direction x, the recesses 55 overlap with the first terminal 21 and the second terminal 22.

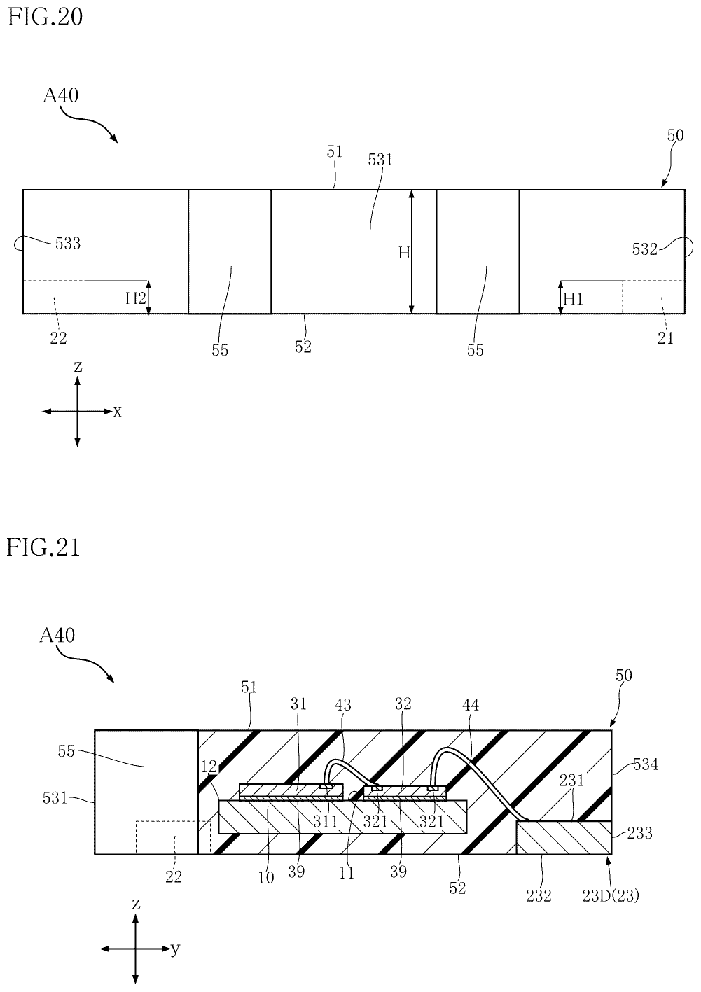

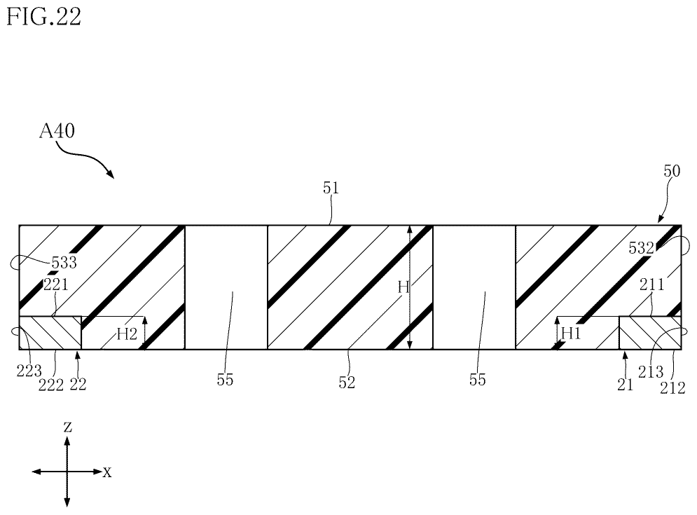

As shown in FIGS. 20 and 22, the dimension H of each recess 55 in the third direction z is greater than the respective dimensions H1 and H2 of the first terminal 21 and the second terminal 22 in the third direction z. In the semiconductor device A40, the dimension H is equal to the distance between the top surface 51 and the bottom surface 52.

Next, the effects of the semiconductor device A40 will be described.

The semiconductor device A40 includes the sealing resin 50 covering a part of each of the first terminal 21 and the second terminal 22, and the first semiconductor element 31 electrically connected to the first terminal 21 and the second terminal 22 and covered with the sealing resin 50. The second terminal 22 is spaced apart from the first terminal 21 in the first direction x. The sealing resin 50 has the first side surface 531 facing in the second direction y and located closest to the first terminal 21 and the second terminal 22 in the second direction y. The first terminal 21 and the second terminal 22 are spaced apart from the first side surface 531. The semiconductor device A40 having such a configuration also allows miniaturization of the device while suppressing electric discharge between the terminals. Further, the semiconductor device A40 has a configuration in common with the semiconductor device A10, thereby achieving the same effect as the semiconductor device A10.

### Fifth Embodiment

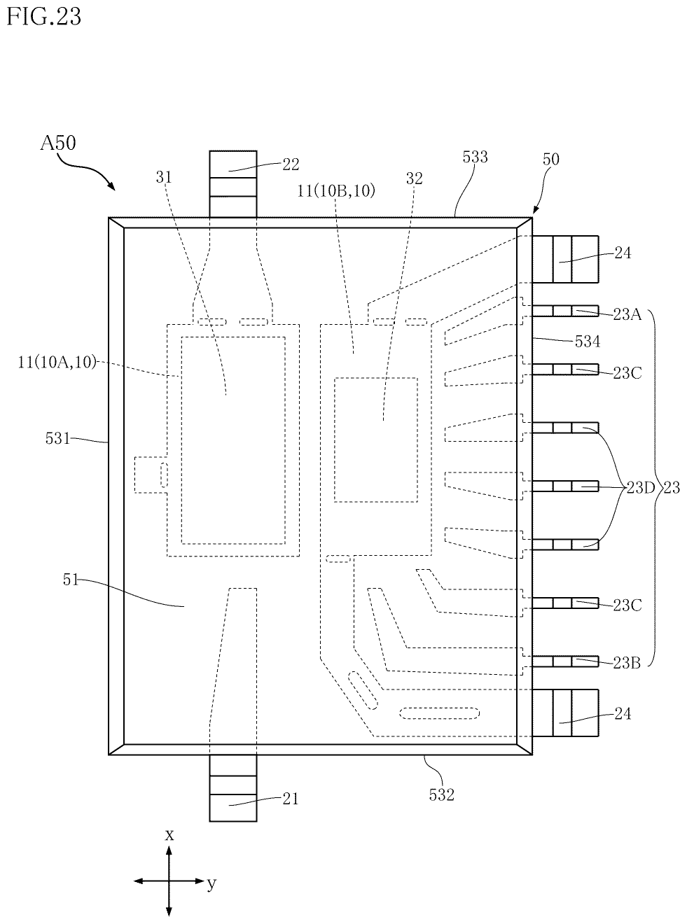

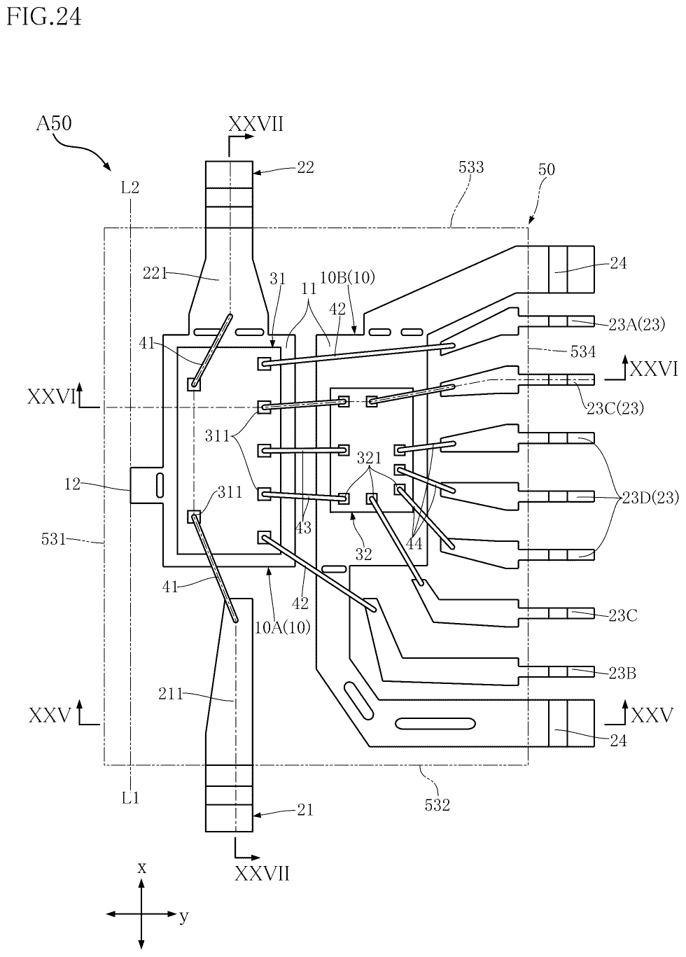

A semiconductor device A50 according to a fifth embodiment of the present disclosure will be described based on FIGS. 23 to 27. In these figures, the elements that are identical or similar to those of the semiconductor device A10 described above are denoted by the same reference signs, and the descriptions thereof are omitted. In FIG. 24, the sealing resin 50 is transparent for the convenience of understanding. In FIG. 24, the outline of the sealing resin 50 is shown by imaginary lines. Each of the XXVI-XXVI line and the XXVII-XXVII line is shown as a single-dot chain line in FIG. 24.

The semiconductor device differs A50 from the semiconductor device A10 in the configurations of the die pad 10, the first terminal 21, the second terminal 22, the third terminals 23, and the two fourth terminals 24. The package type of the semiconductor device A50 is the QFN (Quad Flat Non-leaded package). In the semiconductor device A50, the sealing resin 50 does not have recesses 55.

As shown in FIGS. 23, 24, and 26, the die pad 10 includes a first pad 10A and a second pad 10B. The second pad 10B is located between the first pad 10A and the third terminals 23 in the second direction y. The first semiconductor element 31 is mounted on the mount surface 11 of the first pad 10A. The second semiconductor element 32 is mounted on the mount surface 11 of the second pad 10B. The second terminal 22 is connected to the first pad 10A. The two fourth terminals 24 are connected to the second pad 10B. The first edge 12 is a part of the first pad 10A.

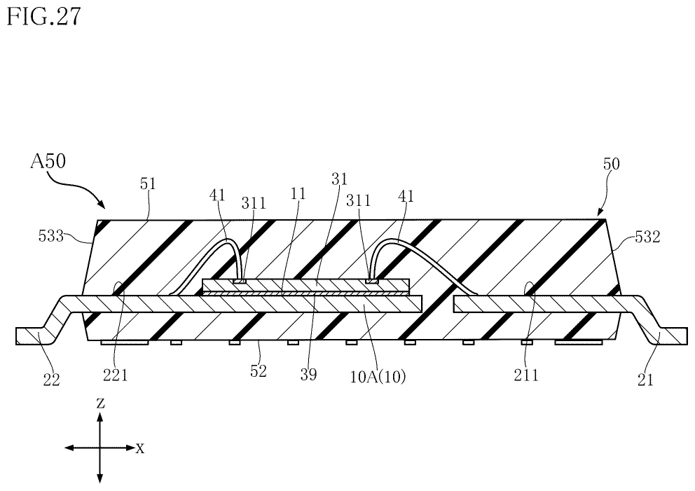

As shown in FIGS. 23 and 27, the first terminal 21 protrudes from the second side surface 532 of the sealing resin 50. The second terminal 22 protrudes from the third side surface 533 of the sealing resin 50. The portions of the first terminal 21 and the second terminal 22 that protrude from the sealing resin 50 are bent toward the side on which the bottom surface 52 of the sealing resin 50 is located in the third direction z. A part of the first obverse surface 211 of the first terminal 21 and a part of the second obverse surface 221 of the second terminal 22 are covered with the sealing resin 50.

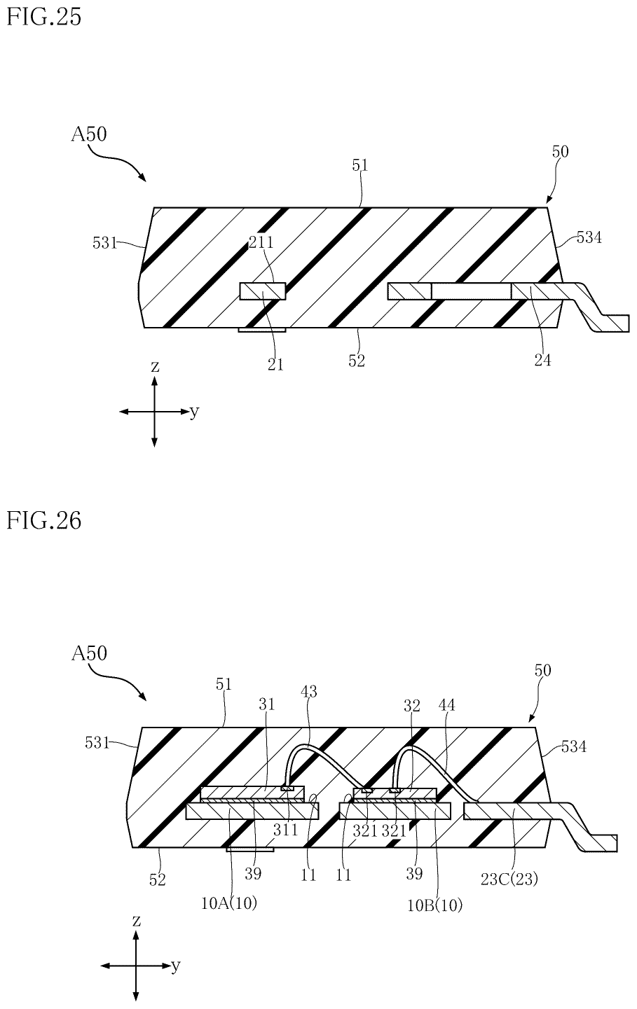

As shown in FIGS. 23 and 25, the third terminals 23 and the two fourth terminals 24 protrude from the fourth side surface 534 of the sealing resin 50. The portions of the third terminals 23 and two fourth terminals 24 that protrude from the sealing resin 50 are bent toward the side on which the bottom surface 52 of the sealing resin 50 is located in the third direction z.

In the semiconductor device A50 as well, the first terminal 21 and the second terminal 22 are spaced apart from the first side surface 531 of the sealing resin 50 as shown in FIG. 24. Also, in the semiconductor device A50 as well, the first terminal 21 and the second terminal 22 are located on opposite sides of the first edge 12 of the first pad 10A in the first direction x. Further, in the semiconductor device A50, the first terminal 21 and the second terminal 22 are located opposite to the first side surface 531 with respect to the first edge 12 in the second direction y.

Next, the effects of the semiconductor device A50 will be described.

The semiconductor device A50 includes the sealing resin 50 covering a part of each of the first terminal 21 and the second terminal 22, and the first semiconductor element 31 electrically connected to the first terminal 21 and the second terminal 22 and covered with the sealing resin 50. The second terminal 22 is spaced apart from the first terminal 21 in the first direction x. The sealing resin 50 has the first side surface 531 facing in the second direction y and located closest to the first terminal 21 and the second terminal 22 in the second direction y. The first terminal 21 and the second terminal 22 are spaced apart from the first side surface 531. The semiconductor device A50 having such a configuration also allows miniaturization of the device while suppressing electric discharge between the terminals. Further, the semiconductor device A50 has a configuration in common with the semiconductor device A10, thereby achieving the same effect as the semiconductor device A10.

The present disclosure is not limited to the above-described embodiments. Various modifications in design may be made freely in the specific structure of each part of the present disclosure.

The present disclosure includes embodiments described in the following clauses.

### Clause 1

A semiconductor device comprising:
a first semiconductor element;
a first terminal electrically connected to the first semiconductor element;
a second terminal electrically connected to the first semiconductor element and spaced apart from the first terminal in a first direction; and
a sealing resin covering the first semiconductor element and a part of each of the first terminal and the second terminal, wherein
the sealing resin includes a first side surface facing in a second direction orthogonal to the first direction and located closest to the first terminal and the second terminal in the second direction, and
the first terminal and the second terminal are spaced apart from the first side surface.

### Clause 2

The semiconductor device according to clause 1, further comprising a die pad on which the first semiconductor element is mounted, wherein,
as viewed in a third direction orthogonal to the first direction and the second direction, the die pad includes a first edge extending in the first direction and located closest to the first side surface in the second direction, and
the first terminal and the second terminal are located on opposite sides of the first edge in the first direction.

### Clause 3

The semiconductor device according to clause 2, wherein the first terminal and the second terminal are located opposite to the first side surface with respect to the first edge in the second direction.

### Clause 4

The semiconductor device according to clause 2, wherein, as viewed in the third direction, the first terminal overlaps with a first extension line extending from one end of the first edge in the first direction.

### Clause 5

The semiconductor device according to clause 4, wherein, as viewed in the third direction, the second terminal overlaps with a second extension line extending from another end of the first edge in the first direction.

### Clause 6

The semiconductor device according to any one of clauses 2 to 5, wherein a dimension of the die pad in the first direction increases as the die pad extends away from a side on which the first side surface is located with respect to the first semiconductor element in the second direction.

### Clause 7

The semiconductor device according to clause 6, wherein a portion of the die pad that is located opposite to the first edge with respect to the first semiconductor element in the second direction protrudes toward opposite sides in the first direction with respect to the first edge.

### Clause 8

The semiconductor device according to any one of clauses 2 to 7, wherein at least a part of the die pad is covered with the sealing resin,
the sealing resin includes a bottom surface facing away from a side on which the first semiconductor element is located with respect to the die pad, and
the first terminal and the second terminal are exposed externally from the bottom surface.

### Clause 9

The semiconductor device according to clause 8, wherein the sealing resin includes a recess located between the first terminal and the second terminal in the first direction, and
the recess overlaps with the first terminal and the second terminal as viewed in the first direction.

### Clause 10

The semiconductor device according to clause 9, wherein the recess is recessed from the bottom surface and extends in the second direction.

### Clause 11

The semiconductor device according to clause 10, wherein the die pad is spaced apart from the bottom surface, and
the recess overlaps with the die pad as viewed in the third direction.

### Clause 12

The semiconductor device according to clause 2 or 3, wherein the sealing resin includes a second side surface and a third side surface facing away from each other in the first direction,
the first terminal is exposed externally from the second side surface, and
the second terminal is exposed externally from the third side surface.

### Clause 13

The semiconductor device according to clause 12, wherein the first terminal protrudes from the second side surface, and
the second terminal protrudes from the third side surface.

### Clause 14

The semiconductor device according to any one of clauses 2 to 13, wherein the first semiconductor element includes a step-down circuit including a plurality of resistor elements.

### Clause 15

The semiconductor device according to clause 14, further comprising:
a second semiconductor element including an operational amplifier; and
a plurality of third terminals electrically connected to the second semiconductor element, wherein
the second semiconductor element is electrically connected to the first semiconductor element,
the second semiconductor element and a part of each of the plurality of third terminals are covered with the sealing resin, and
the plurality of third terminals are located opposite to the first side surface with respect to the die pad in the second direction.

### Clause 16

The semiconductor device according to clause 15, wherein the second semiconductor element is mounted on the die pad.

### Clause 17

The semiconductor device according to clause 15 or 16, further comprising two fourth terminals spaced apart from each other in the first direction and supporting the die pad, wherein
a part of each of the two fourth terminals is covered with the sealing resin, and
the plurality of third terminals are located between the two fourth terminals in the first direction.

REFERENCE NUMERALS

| | | | |
|---|---|---|---|
| A10, A20, A30, | Semiconductor device | | |
| A40, A50: | | | |
| 10: | Die pad | 10A: | First pad |
| 10B: | Second pad | 11: | Mount surface |
| 12: | First edge | 21: | First terminal |
| 211: | First obverse surface | 212: | First reverse surface |
| 213: | First end surface | 22: | Second terminal |
| 221: | Second obverse surface | 222: | Second reverse surface |
| 223: | Second end surface | 23: | Third terminal |
| 23A: | A-terminal | 23B: | B-terminal |
| 23C: | C-terminal | 23D: | D-terminal |
| 231: | Third obverse surface | 232: | Third reverse surface |
| 233: | Third end surface | 24: | Fourth terminal |
| 241: | Fourth obverse surface | 242: | Fourth reverse surface |
| 243: | Fourth end surface | 244: | Connecting surface |
| 31: | First semiconductor | 311: | First electrode |
| | element | | |
| 32: | Second semiconductor | 321: | Second electrode |
| | element | | |
| 39: | Bonding layer | 41: | First wire |
| 42: | Second wire | 43: | Third wire |
| 44: | Fourth wire | 50: | Sealing resin |
| 51: | Top surface | 52: | Bottom surface |
| 531: | First side surface | 532: | Second side surface |
| 533: | Third side surface | 534: | Fourth side surface |
| 55: | Recess | L1: | First extension line |
| L2: | Second extension line | x: | First direction |
| y: | Second direction | z: | Third direction |

1. A semiconductor device comprising:
a first semiconductor element;
a first terminal electrically connected to the first semiconductor element;
a second terminal electrically connected to the first semiconductor element and spaced apart from the first terminal in a first direction; and
a sealing resin covering the first semiconductor element and a part of each of the first terminal and the second terminal, wherein
the sealing resin includes a first side surface facing in a second direction orthogonal to the first direction and located closest to the first terminal and the second terminal in the second direction, and
the first terminal and the second terminal are spaced apart from the first side surface.

2. The semiconductor device according to claim 1, further comprising a die pad on which the first semiconductor element is mounted, wherein,
as viewed in a third direction orthogonal to the first direction and the second direction, the die pad includes a first edge extending in the first direction and located closest to the first side surface in the second direction, and
the first terminal and the second terminal are located on opposite sides of the first edge in the first direction.

3. The semiconductor device according to claim 2, wherein the first terminal and the second terminal are located opposite to the first side surface with respect to the first edge in the second direction.

4. The semiconductor device according to claim 2, wherein, as viewed in the third direction, the first terminal overlaps with a first extension line extending from one end of the first edge in the first direction.

5. The semiconductor device according to claim 4, wherein, as viewed in the third direction, the second terminal overlaps with a second extension line extending from another end of the first edge in the first direction.

6. The semiconductor device according to claim 2, wherein a dimension of the die pad in the first direction increases as the die pad extends away from a side on which the first side surface is located with respect to the first semiconductor element in the second direction.

7. The semiconductor device according to claim 6, wherein a portion of the die pad that is located opposite to the first edge with respect to the first semiconductor element in the second direction protrudes toward opposite sides in the first direction with respect to the first edge.

8. The semiconductor device according to claim 2, wherein at least a part of the die pad is covered with the sealing resin,
the sealing resin includes a bottom surface facing away from a side on which the first semiconductor element is located with respect to the die pad, and
the first terminal and the second terminal are exposed externally from the bottom surface.

9. The semiconductor device according to claim 8, wherein the sealing resin includes a recess located between the first terminal and the second terminal in the first direction, and
the recess overlaps with the first terminal and the second terminal as viewed in the first direction.

10. The semiconductor device according to claim 9, wherein the recess is recessed from the bottom surface and extends in the second direction.

11. The semiconductor device according to claim 10, wherein the die pad is spaced apart from the bottom surface, and
the recess overlaps with the die pad as viewed in the third direction.

12. The semiconductor device according to claim 2, wherein the sealing resin includes a second side surface and a third side surface facing away from each other in the first direction,
the first terminal is exposed externally from the second side surface, and
the second terminal is exposed externally from the third side surface.

13. The semiconductor device according to claim 12, wherein the first terminal protrudes from the second side surface, and
the second terminal protrudes from the third side surface.

14. The semiconductor device according to claim 2, wherein the first semiconductor element includes a step-down circuit including a plurality of resistor elements.

15. The semiconductor device according to claim 14, further comprising:
a second semiconductor element including an operational amplifier; and
a plurality of third terminals electrically connected to the second semiconductor element, wherein
the second semiconductor element is electrically connected to the first semiconductor element,
the second semiconductor element and a part of each of the plurality of third terminals are covered with the sealing resin, and
the plurality of third terminals are located opposite to the first side surface with respect to the die pad in the second direction.

16. The semiconductor device according to claim 15, wherein the second semiconductor element is mounted on the die pad.

17. The semiconductor device according to claim 15, further comprising two fourth terminals spaced apart from each other in the first direction and supporting the die pad, wherein
a part of each of the two fourth terminals is covered with the sealing resin, and
the plurality of third terminals are located between the two fourth terminals in the first direction.
